(19) United States
(12) Patent Application Publication
(10) Pub. No.: US 2004/0171277 A1
(43) Pub. Date: Sep. 2, 2004

(54) Method of forming a conductive metal line over a semiconductor wafer

(75) Inventors: Jun-Hwan Oh, Incheon (KR); Hong-Seong Son, Suwon-city (KR); Chan-Geun Park, Suwon-city (KR); Sang-Rok Hah, Seoul (KR)

Correspondence Address: Frank Chau, Esq., F. CHAU & ASSOCIATES, LLC, 1900 Hempstead Turnpike, East Meadow, NY, 11554, US

(73) Assignee: Samsung Electronics Co., Ltd.

(21) Appl. No.: 10/776,908

(22) Filed: Feb. 11, 2004

(30) Foreign Application Priority Data
Feb. 12, 2003 (KR) 2003-8927

(51) Int. Cl. H01L 21/31

(52) U.S. Cl. 438/758

(57) ABSTRACT

A method of forming a conductive metal line over a semiconductor wafer including forming a diffusion barrier layer over a top surface of the semiconductor wafer, and forming a seed metal layer over the diffusion barrier layer. A conductive metal layer is formed over the seed metal layer, the conductive metal layer selectively exposing a portion of the seed metal layer on the peripheral region of the semiconductor wafer. A partial etching process is performed on the conductive metal layer to remove the portion of the seed metal layer.

This application claims priority to Korean Patent Application 2002-24799 filed on May 6, 2002.

### BACKGROUND

1. Technical Field

The present disclosure relates to a method of forming a metal line of a semiconductor device, more particularly, to a method of forming a conductive metal line over a semiconductor wafer.

2. Disclosure of Related Art

In a conventional semiconductor fabrication process of a semiconductor device, metallic lines are used to electrically connect discrete devices, such as transistors and capacitors, to one another. The fabrication method typically uses an aluminum layer as the metallic layer.

As the degree of integration of semiconductor devices has become higher, the aluminum layer has been replaced with a highly reliable metallic layer, such as a copper layer. This is because the copper layer has a higher conductivity and a better electromigration characteristic than the aluminum layer.

A copper atom generally has a higher diffusivity than an aluminum atom, and thus there is a higher probability of the copper atom infiltrating into a semiconductor wafer via an interlayer insulator. It is required that the copper layer be enclosed by a diffusion barrier layer because of the higher diffusivity. Also, the known dry etching process cannot transform the copper layer to fine copper lines using process gases.

To cope with the problems described above, a damascene process is used in the semiconductor fabrication process of a highly integrated semiconductor device.

A conventional method of forming the copper lines using the damascene process involves forming an interlayer insulating layer with grooves on the semiconductor wafer, forming a diffusion barrier layer and a seed copper layer in sequence on a top surface of the semiconductor wafer, applying an electroplating technique to form a copper layer on the seed copper layer, and planarizing the copper layer until the interlayer insulating layer is exposed. The copper layer and/or the seed copper layer can remain on a peripheral region, especially on a bevel of the semiconductor wafer. This copper layer remaining on the peripheral region of the semiconductor wafer could contaminate a wafer cassette and a transfer arm that are employed to transfer the semiconductor wafer. In addition, the remaining copper layer may penetrate into the semiconductor wafer through the interlayer insulating layer and deteriorate characteristics of the semiconductor device. Therefore, it is absolutely necessary to remove the copper layer remaining on the semiconductor wafer edge.

A method for removing the copper layer remaining on the semiconductor wafer edge is disclosed in US patent publication No. US 2002/0106905 A1 to Tran et al. This method involves depositing a diffusion barrier layer, a seed copper layer and a copper layer in sequence on the top surface of a semiconductor wafer. A protection layer, such as a photoresist layer, is formed on the semiconductor wafer having the copper layer. The photoresist layer on a peripheral region of the semiconductor wafer is removed by using the known edge-bead removal process. As this time, the copper layer is exposed on the peripheral region of the semiconductor wafer. A wet etch is performed on the semiconductor wafer to remove the copper layer and its underlying seed copper layer on the peripheral region of the semiconductor wafer.

The above-described method requires the use of a protection layer, such as a photoresist layer, and thus requires additional processes such as coating the photoresist layer, performing the edge-bead removal process and removing the photoresist layer. The additional processes may cause a decrease in throughput of the overall semiconductor fabrication process. Furthermore, the use of the photoresist layer may contaminate the wet etchant.

### SUMMARY OF THE INVENTION

Various exemplary ebmodiments of the present invention provide a method of forming a conductive metal line over a semiconductor wafer in which a portion of a metal layer on a peripheral region of the semiconductor wafer is removed without employing a photoresist layer.

A method of forming a conductive metal line over a semiconductor wafer according to an embodiment of the invention includes forming a diffusion barrier layer over a top surface of the semiconductor wafer, and forming a seed metal layer over the diffusion barrier layer. A conductive metal layer is formed over the seed metal layer, the conductive metal layer selectively exposing a portion of the seed metal layer on the peripheral region of the semiconductor wafer. A partial etching process is performed on the conductive metal layer to remove the portion of the seed metal layer and to expose the diffusion barrier layer on the peripheral region of the semiconductor wafer.

A method of forming a conductive metal line over a semiconductor wafer according to another embodiment of the invention includes forming a conductive metal layer over the semiconductor wafer. A partial etching process is performed on the semiconductor wafer to partially remove the conductive metal layer.

### BRIEF DESCRIPTION OF THE DRAWINGS

Various exemplary embodiments of the present invention will become readily apparent by reference to the following detailed description when considered in conjunction with the accompanying drawings wherein:

FIG. 1 is a cross sectional view of a semiconductor wafer on which metal layers are formed according to an embodiment of the invention;

FIG. 2 is a cross sectional view of a clamshell in which a semiconductor wafer is mounted according to an embodiment of the invention;

FIG. 3a is a plane view showing mutual positional relationship of a semiconductor wafer, a lip seal and a cathode contact according to an embodiment of the invention;

FIG. 3b is a perspective view taken along line I-I′of the cathode contact of FIG. 3a;

FIG. 4 is a cross sectional view of a clamshell in which a semiconductor wafer is mounted according to an embodiment of the invention; and

FIGS. 5 through 11 show steps of a method of forming a conductive metal line according to an embodiment of the present invention.

### DETAILED DESCRIPTION OF PREFERRED EMBODIMENTS

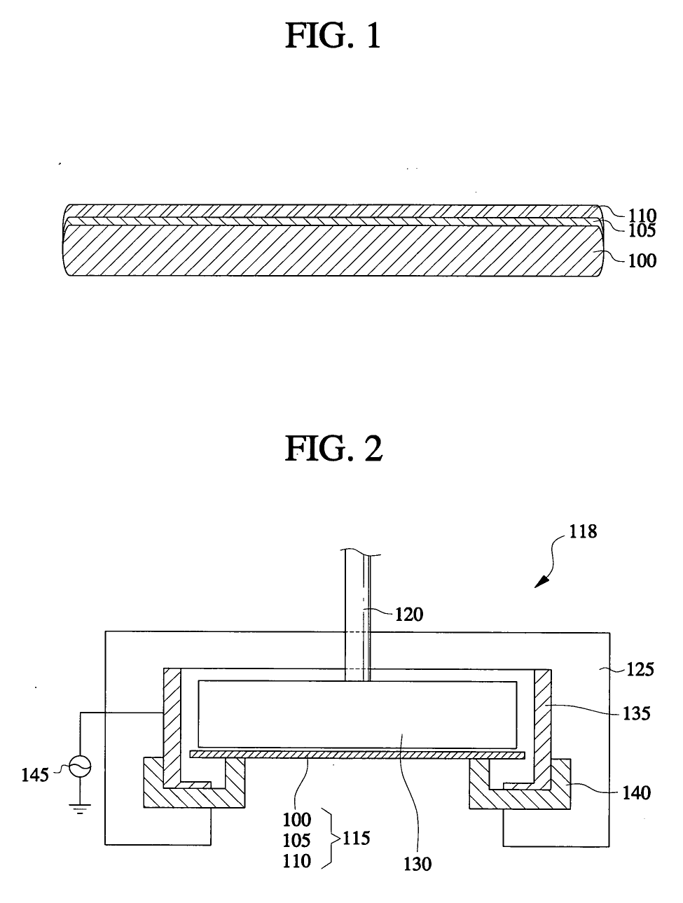

FIG. 1 is a cross-sectional view of a semiconductor wafer on which metallic layers are formed according to an exemplary embodiment of the present invention, and FIG. 2 is a cross-sectional view of a clamshell in which a semiconductor wafer is mounted according to an embodiment of the present invention.

Referring to FIG. 1, the semiconductor wafer 100 having a plurality of lower lines (not shown) is prepared. An interlayer insulating layer (not shown) covering the lower lines is formed. A plurality of trenches (not shown) is formed in the interlayer insulating layer. The trenches expose predetermined portions of top surfaces of the lower lines. A diffusion barrier layer 105 and a seed copper layer 110 are sequentially formed in the trenches and on the interlayer insulating layer. The diffusion barrier layer 105 and the seed copper layer 110 are formed using a PVD (Physical Vapor Deposition) method. Thus, a bevel of the semiconductor wafer 100 is covered with the diffusion barrier layer 105 and the seed copper layer 110. The diffusion barrier layer 105 preferably is a TaN layer, but may also be formed using Ti and TiN layers stacked in sequence.

Referring to FIG. 2, a clamshell 118 in which a semiconductor wafer 115 is mounted is prepared. As this time, the semiconductor wafer 115 includes the diffusion barrier layer 105 and the seed copper layer 110 of FIG. 1. The clamshell 118 has a main body 125 in which a lip seal 140 and a cathode contact 135 are mounted. The semiconductor wafer 115 is placed on the lip seal 140, which is preferably made of a rubber material. The cathode contact 135 is an electric conductor and the main body 125 is an insulator. The main body 125 has a plurality of electric wires for applying an external power source 145 to the semiconductor wafer 115. Also, the main body 125 includes a pressure part 130 having a support part 120 which can move vertically. The pressure part 130 presses the semiconductor wafer 115 to place the semiconductor wafer 115 in contact with the cathode contact 135.

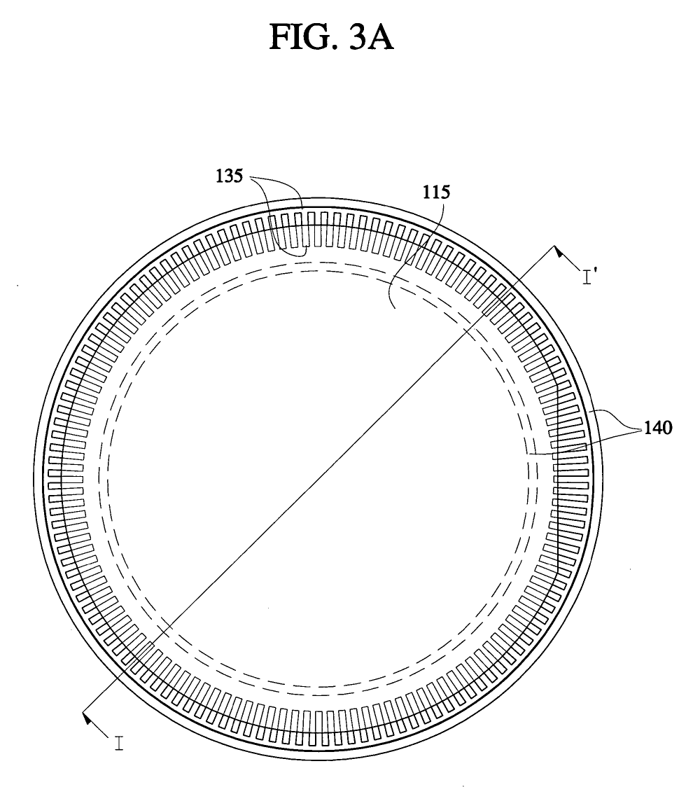

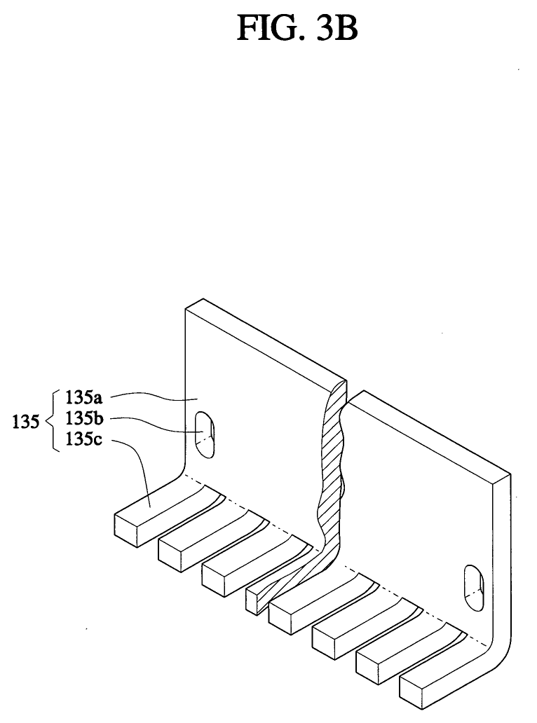

FIG. 3a is a plane view showing mutual positional relationship of a semiconductor wafer, a lip seal and a cathode contact according to an embodiment of the invention, and FIG. 3b is a perspective view taken along line I-I′ of the cathode contact of FIG. 3a.

Referring to FIGS. 3a and 3b, the semiconductor wafer 115 is placed on the cathode contact 135 equipped on the lip seal 140. At this time, the semiconductor wafer 115 includes the diffusion barrier layer 105 and the seed copper layer 110 stacked in sequence. The lip seal 140 has a cylindrical shape such as a ribbon. The cathode contact 135 is divided into an upper body 135a and a lower body 135c. The lower body 135c has a plurality of contact nodes. The cathode contact 135 is an easily transformable electric conductor, and each of a plurality of cathode contacts 135 is connected to the lip seal 140 via connecting parts 135b. The semiconductor wafer 115 is positioned on the cathode contact 135, more particularly, the peripheral region of the semiconductor wafer is positioned on the lower body 135c of the cathode contact 135.

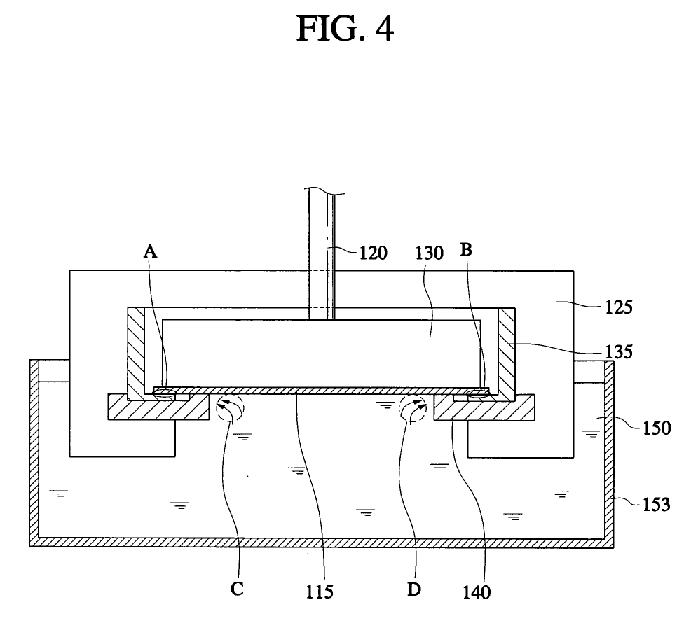

FIG. 4 is a cross-sectional view of an electroplating bath mounted with a clamshell according to an embodiment of the present invention.

Referring to FIG. 4, pressure is applied to the press portion 130 through the support 120 inside the clamshell 118 of FIG. 2, so that the press portion 130 presses the lip seal 140 via the semiconductor wafer 115 to bring the semiconductor wafer 115 into contact with the cathode contact 135. At this time, the semiconductor wafer 115 includes the diffusion barrier layer 105 and the seed copper layer 110 stacked in sequence. The clamshell 118 is dipped into a plating solution 150 in an electroplating bath 153, to form the copper layer (not shown) on the semiconductor wafer 115. At this time, an external source power is applied to the clamshell 118 and the electroplating bath 153. Thus, the semiconductor wafer 115 and the plating solution 150 have different electric polarities. The plating solution 150 preferably includes copper sulphate (CuSO₄), sulphuric acid (H₂SO₄), hydrochloric acid (HCl), and other additives. The lip seal 140, which is pressed by the press portion 130, prevents the plating solution 150 from flowing into the cathode contact 135, such as via flow streams C and D.

Nevertheless, the plating solution 150 occasionally flows into the cathode contact 135 when the lip seal 140 is worn out due to aging or incomplete suppression by the press part 130. In that case, the semiconductor wafer 115 may have unwanted by-products on predetermined portions A and B in contact with the cathode contact 135.

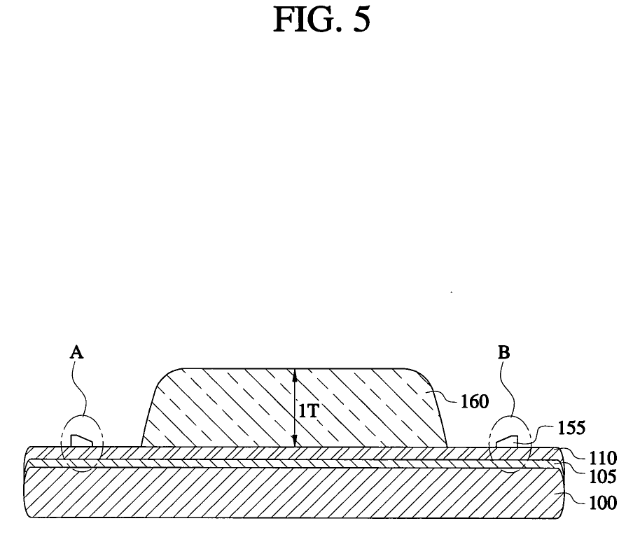

FIG. 5 through FIG. 11 are cross-sectional views and plane views illustrating a method of selectively removing a copper layer on the peripheral region of a semiconductor wafer according to an embodiment of the present invention.

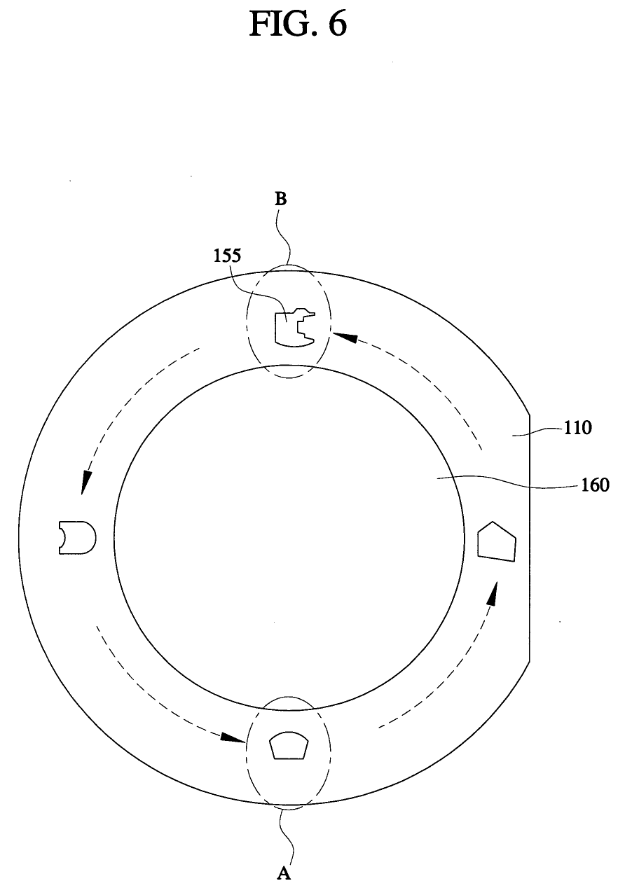

Referring to FIGS. 5 to 6, a copper layer 160 and unwanted by-products 155 are formed on a region having a predetermined radius in a radial shape from the center of the semiconductor wafer 100 and on the peripheral region of the semiconductor wafer 100, respectively. The copper layer 160 is formed to a thickness of 1T thicker than the seed copper layer 110. At this time, the copper layer 160 is formed on an upper portion of the semiconductor wafer 100 to expose the seed copper layer 110 on the peripheral region of the semiconductor wafer 100. The area of the copper layer 160 is closely related to a diameter of the lip seal 140 mounted in the clamshell 118. Hereinafter, the unwanted by-products 155 will be referred to as residual copper layers.

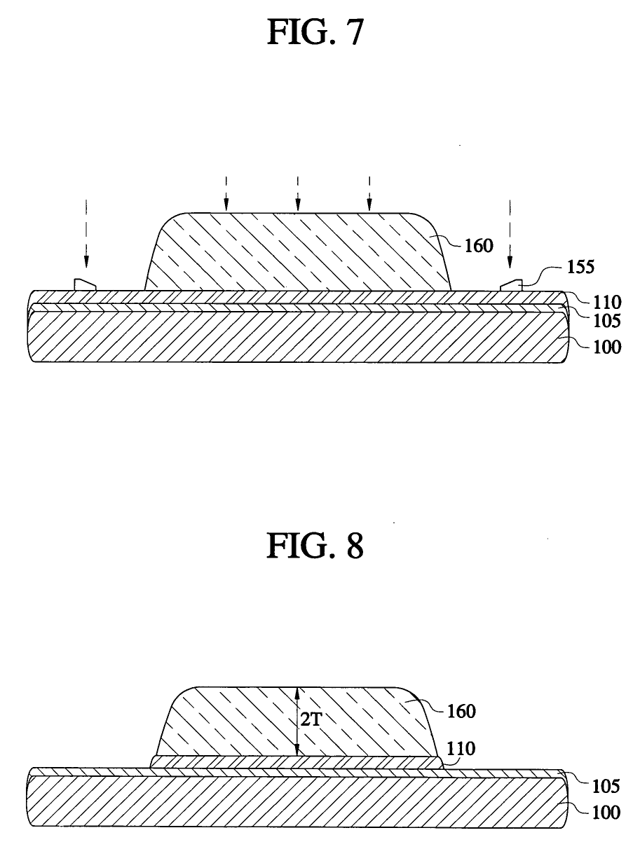

Referring now to FIGS. 7 through 9, a wet etching process(E) is carried out on the semiconductor wafer 100 to partially etch the copper layer 160 and to selectively remove the seed copper layer 110 exposed by the copper layer 160. The wet etching process(E) results in the copper layer 160 having a thickness of 2T.

A wet etchant used for the wet etching process(E) typically is a fluorine-base chemical mixture, preferably a chemical mixture comprising DHF or DHF+H₂O₂. Also, the wet etchant may be one selected from a H₂SO₄, HCl and H₂O₂-base chemical mixture, a H₃PO₄-base chemical mixture, and a HNO₃-base chemical mixture.

In addition, the wet etching process(E) is carried out using one selected from a wet bench dipping method, a single spin method and a spraying type method. The wet bench dipping method and the spray type method involve wet-etching at least one semiconductor wafer equipped in a cassette at a time, and the single spin method involves wet-etching one single semiconductor wafer at a time. The wet bench dipping method, the single spin method and the spraying type method are well known wet etch processes.

Furthermore, the wet etching process(E) is effective for removing copper atoms that might exist on the peripheral region, on the bevel and on the lower surface of the semiconductor wafer 100. Thus, the wet etching process(E) reduces contaminant sources due to the copper atoms, and reduces attack on semiconductor fabrication equipment used for subsequent processes.

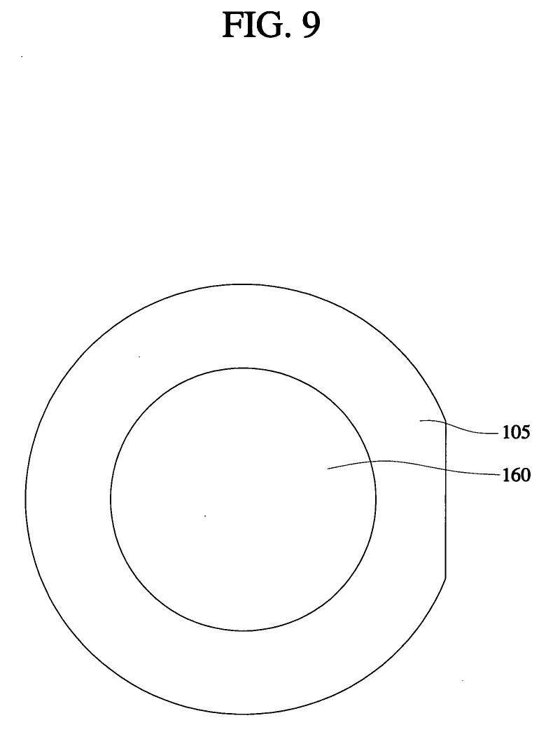

The semiconductor wafer 100, on which the wet etching process(E) is performed, has a ring shape and an inner circle as shown in the plane view of FIG. 9. The ring shape on the peripheral region of the semiconductor wafer 100 represents the diffusion barrier layer 105, and the inner circle on the central region of the semiconductor wafer 100 represents the copper layer 160 formed by the wet etching process. At this time, the semiconductor wafer 100 having the diffusion barrier layer 105 has no residue copper layers 155 on its top surface.

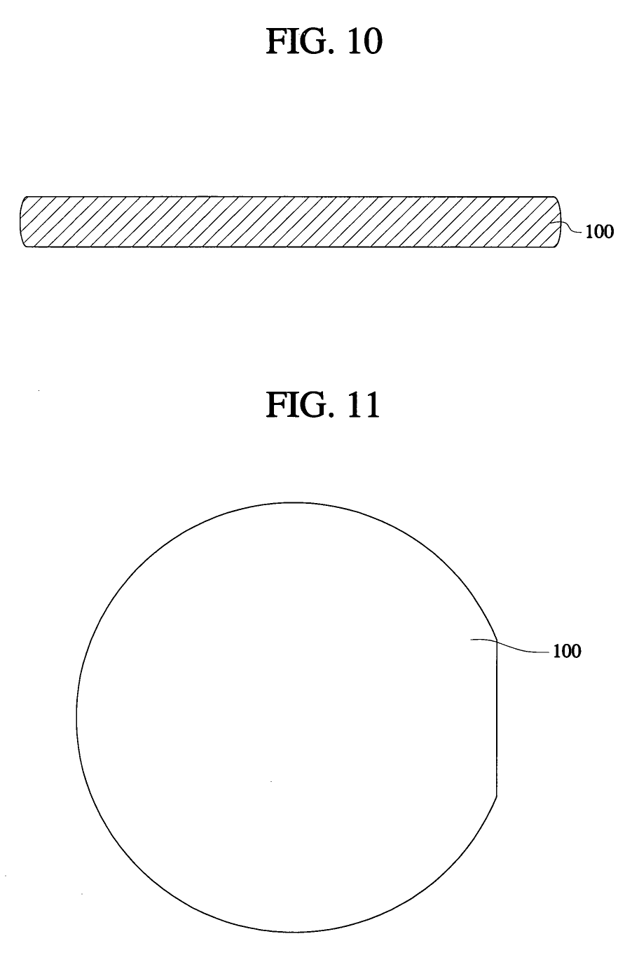

Referring to FIGS. 10 and 11, a chemical mechanical polishing process is performed on the semiconductor wafer 100 having the copper layer 160, the seed copper layer 110 and the diffusion barrier layer 105 of FIG. 8. The chemical mechanical polishing process is performed using the interlayer insulating layer (not shown) as an etching buffer layer to etch the copper layer 160. After the chemical mechanical polishing process, the copper layer 160, the seed copper layer 110 and the diffusion barrier layer 105 are filled into the plurality of trenches of the interlayer insulating layer to form upper lines (not shown) on the upper surface of the semiconductor wafer 100. The upper lines are contacted with the lower lines of FIG. 1 via the trenches.

In addition, if the residue copper layers 155 exist on the peripheral region of the semiconductor wafer 100 as shown in FIG. 6, it is highly possible that at least one scratch is formed on the semiconductor wafer 100 during the chemical mechanical polishing process due to the residue copper layers 155. However, the semiconductor wafer 100 according to an embodiment of the present invention has no residue copper layers 155 on its peripheral region. Hence, no scratch is found on the top surface of the semiconductor wafer 100 after the chemical mechanical polishing process.

As described the above, residue copper layers are eliminated by performing the wet etching process sequentially on the semiconductor wafer with the diffusion barrier layer, the seed copper layer and the copper layer prior to the chemical mechanical polishing process. The wet etching process can effectively protect scratches from occurring on the top surface of the semiconductor wafer. Accordingly, the present invention can reduce the effect of contamination sources due to residue copper layers on the semiconductor fabrication equipment, thereby enhancing the performance of the semiconductor device.

While the present invention has been particularly shown and described with reference to exemplary embodiments thereof, it will be understood by those skilled in the art that the foregoing and other changes in form and details may be made therein without departing from the spirit and scope of the present invention.

What is claimed is:

1. A method of forming a conductive metal lineover a semiconductor wafer, comprising the steps of:
forming a diffusion barrier layer over a top surface of the semiconductor wafer;
forming a seed metal layer over the diffusion barrier layer;
forming a conductive metal layer over the seed metal layer, the conductive metal layer selectively exposing a portion of the seed metal layer on the peripheral region of the semiconductor wafer; and
performing a partial etching process on the conductive metal layer to remove the portion of the seed metal layer and to expose the diffusion barrier layer on the peripheral region of the semiconductor wafer.

2. The method according to claim 1, wherein the conductive metal layer is made of copper.

3. The method according to claim 2, wherein the diffusion barrier layer comprises a TaN layer.

4. The method according to claim 2, wherein the diffusion barrier layer comprises a Ti layer and a Tin layer stacked in sequence.

5. The method according to claim 1, wherein the steps of forming the diffusion barrier layer and the conductive metal layer comprise PVD (Physical Vapor Deposition).

6. The method according to claim 1, wherien the step of forming the conductive metal layer comprises electroplating.

7. The method according to claim 1, wherein the partial etching process is carried out using a wet etchant selected from a group consisting of a fluorine-base chemical mixture, a H₂SO₄, HCl and H₂O₂-base chemical mixture, a H₃PO₄-base chemical mixture, and a HNO₃-base chemical mixture.

8. The method according to claim 1, wherein the partial etching process is carried out using a wet etching method selected from a group consisting of a wet bench dipping method, a single spin method, and a spraying type method.

9. The method according to claim 1, further comprising the step of:
performing a chemical mechanical polising process on the the diffusion barrier layer, the seed metal layer and the conductive metal layer after performing the wet etching process.

10. The method according to claim 1, wherein the conductive metal layer is formed to a greater thickness than that of the seed metal layer.

11. A method of forming a conductive metal line over a semiconductor wafer, comprising the steps of:
forming a conductive metal layer over the semiconductor wafer;
performing a partial etching process on the semiconductor wafer to partially remove the conductive metal layer.

12. The method of claim 11, wherein the conductive metal layer is made of copper.

13. The method of claim 11, further comprising:
forming a diffusion barrier layer over the semiconductor wafer; and
forming a seed metal layer over the diffusion barrier layer, the conductive metal layer formed over the seed metal layer and exposing a portion of the seed metal layer on the peripheral region of the semiconductor wafer.

14. The method of claim 13, wherein the portion of the seed metal layer exposed by the conductive metal layer is removed during the partial etching process.

15. The method of claim 11, wherein the partial etching process is carried out using a wet etchant selected from a group consisting of a fluorine-base chemical mixture, a H₂SO₄, HCl and H₂O₂-base chemical mixture, a H₃PO₄-base chemical mixture, and a HNO₃-base chemical mixture.

16. The method of claim 11, wherein the partial etching process is carried out using a wet etching method selected from a group consisting of a wet bench dipping method, a single spin method, and a spraying type method.
